(19) United States
(12) Patent Application Publication
(10) Pub. No.: US 2008/0082874 A1
(43) Pub. Date: Apr. 3, 2008

(54) FBM generation device and FBM generation method

(75) Inventor: Takayuki Kato, Kasugai (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/905,322

(22) Filed: Sep. 28, 2007

(30) Foreign Application Priority Data
Sep. 28, 2006 (JP) 2006-265865

(51) Int. Cl. G11C 29/08; G06F 11/26

(52) U.S. Cl. 714/723; 714/E11.159

(57) ABSTRACT

A fail bit map generation device quickly generating an FBM identifies an abnormal address from a first mismatch detection cycle number obtained in a shipment test and shipment sequence information used in the shipment test. The fail bit map generation device generates a bit identifying pattern that does not perform reading and writing at an address determined as being normal in the shipment test to compensate for read data information that is insufficient for generating the FBM. The fail bit map generation device identifies an abnormal bit from a second mismatch detection cycle number obtained by a tester with the bit identifying pattern and generates the FBM from the abnormal bit and the abnormal address.

### CROSS-REFERENCE TO RELATED APPLICATIONS

This application is based upon and claims the benefit of priority from prior Japanese Patent Application No. 2006-265865, filed on Sep. 28, 2006, the entire contents of which are incorporated herein by reference.

### BACKGROUND

The embodiments discussed herein are directed to a device and a method for generating a fail bit map (FBM).

A built-in self-test (BIST) is nowadays often conducted in place of a SCAN test during final test, or shipment test, of a semiconductor memory device embedded in a semiconductor integrated circuit device. A fail bit map (FBM) is generated to analyze failures in the semiconductor memory device. The FBM includes a failure address of the semiconductor memory device and read data of the failure address.

Serial input of an address and serial output of data are necessary for the SCAN test to carry out a single read operation. Further, serial input of an address and data is necessary for the SCAN test to carry out a single write operation. In the SCAN test that requires serial input/output of address and data, as the capacity of the semiconductor memory device subject to testing increases, the time required for the test becomes longer and the memory capacity of the tester becomes insufficient.

Japanese Laid-Open Publication No. 2005-332492 describes an example of the BIST. In this publication, an address or data is provided to a RAM from an address generation circuit or a data generation circuit embedded in a semiconductor integrated circuit device. A comparison circuit compares an expected value generated by an expected data generation device and output data of the RAM. The comparison result is held in a test result register. Therefore, the BIST does not perform serial input/output and completes the test in a shorter time than the SCAN test. The BIST, which is capable of continuously reading data, has an advantage in that it can detect abnormalities that appear only when continuous operation is performed at high speeds while changing addresses.

The failure diagnosis circuit of the publication includes an address generator for outputting an address, a failure diagnosis start address register for holding a failure diagnosis start address, and a failure diagnosis enable generator for determining whether or not the address output from the address generator belongs to a range that is calculated based on the failure diagnosis start address. The failure diagnosis circuit of the publication includes a comparator for determining whether or not the output data output from the RAM in response to the address output of the address generator matches the expected value. An error address register stops the operation of the address generator and records the address if the address output from the address generator belongs to the calculated range and the output data does not match the expected value. In a test that uses the conventional failure diagnosis circuit, a range of addresses of which normality is not known is tested to obtain a range of addresses of normality is known. The conventional failure diagnosis circuit executes such a test for a number of times to search for all the failure addresses of the RAM and generate the FBM.

### SUMMARY

It is an aspect of the embodiments discussed herein to provide a fail bit map generation device generating a fail bit map for a semiconductor memory device embedded in a semiconductor integrated circuit device, the fail bit map generation device generating the fail bit map in cooperation with a tester testing the semiconductor integrated circuit device and a built-in self-test circuit, embedded in the semiconductor integrated circuit device, diagnosing the semiconductor memory device, wherein the built-in self-test circuit sets a mismatch detection flag to ON when an output of the semiconductor memory device and an expected value generated by the built-in self-test circuit are mismatched during a period in which the tester is conducting a shipment test on the semiconductor integrated circuit device, the fail bit map generation device including an abnormal address identifying unit identifying an abnormal address from a first mismatch detection cycle number when the mismatch detection flag is set to ON and shipment test sequence information, which is a sequence of the shipment test, a bit identifying pattern generation unit generating a bit identifying pattern, the bit identifying pattern being a pattern of m+1 cycles in which reading is started from a state of the built-in self-test circuit corresponding to m cycles before when the mismatch detection flag is set to ON and operation of the built-in self-test circuit is ended when the mismatch detection flag is set to ON, and a fail bit map generation unit identifying an abnormal bit from a second mismatch detection cycle number indicating that the output of the semiconductor memory device, which is obtained when the tester tests the semiconductor memory device with the bit identifying pattern, and an expected value in the bit identifying pattern do not match and generating the fail bit map from the identified abnormal bit and the abnormal address.

### BRIEF DESCRIPTION OF THE DRAWINGS

The embodiments, together with objects and advantages thereof, may best be understood by reference to the following description of the embodiments together with the accompanying drawings in which:

FIG. 1 is a block diagram of a failure diagnosis device according to a preferred embodiment;

FIG. 2 is a block diagram of a semiconductor integrated circuit device;

FIG. 3 is a block diagram of an FBM generation device in the failure diagnosis device of the preferred embodiment;

FIG. 4 is a block diagram of a semiconductor integrated circuit device tested by the failure diagnosis device of FIG. 1;

FIG. 5 is a chart showing an operation sequence executed by the BIST circuit;

FIG. 6 is a chart showing shipment test sequence information;

FIG. 7 is a sequence diagram of a bit identifying pattern;

FIG. 8 is a block diagram of the semiconductor integrated circuit device undergoing bit identification in the preferred embodiment; and

FIG. 9 is a diagram showing an FBM of the preferred embodiment.

### DETAILED DESCRIPTION OF THE PREFERRED EMBODIMENTS

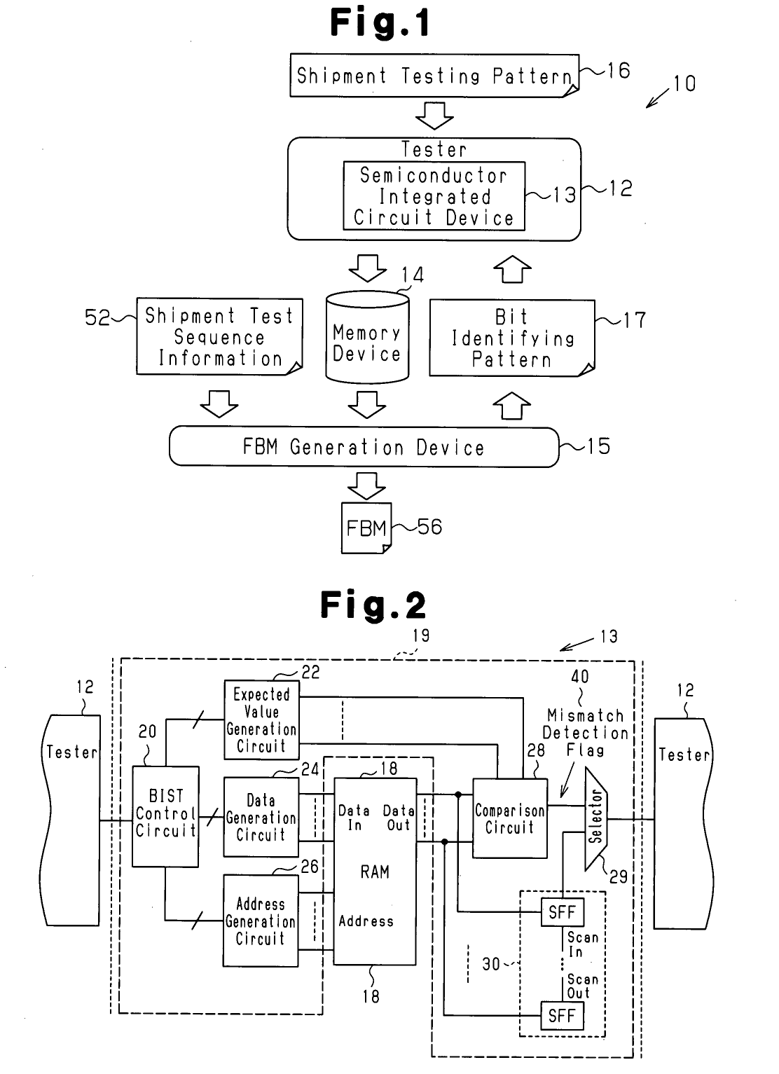

A failure diagnosis device 10 according to a preferred embodiment will now be described. As shown in FIG. 1, the failure diagnosis device 10 includes a tester 12, a semiconductor integrated circuit device 13, a memory device 14, and an FBM generation device 15.

The tester 12 receives a shipment testing pattern 16, tests the semiconductor integrated circuit device 13, and determines whether or not the semiconductor integrated circuit device 13 is normal. The shipment testing pattern 16 is a pattern that operates the semiconductor integrated circuit device 13 for each cycle number in the shipment test. The tester 12 also uses a bit identifying pattern 17 to generate information for identifying an anomalous bit, that is, abnormal bit of the semiconductor memory device 13 (e.g., RAM 18) embedded in the semiconductor integrated circuit device 13, and outputs the information. The identification of the abnormal bit will be described hereafter.

As shown in FIG. 2, the semiconductor integrated circuit device 13 includes a RAM 18, serving as the semiconductor memory device, and a BIST circuit 19 for testing the RAM 18. The RAM 18 includes a plurality of memory cells distinguished from each other by a plurality of addresses. In a write mode, in response to an address and data, the RAM 18 stores the data in the memory cell to which the address is assigned. In a read mode, in response to an address, the RAM 18 outputs the data stored in the memory selected by the address.

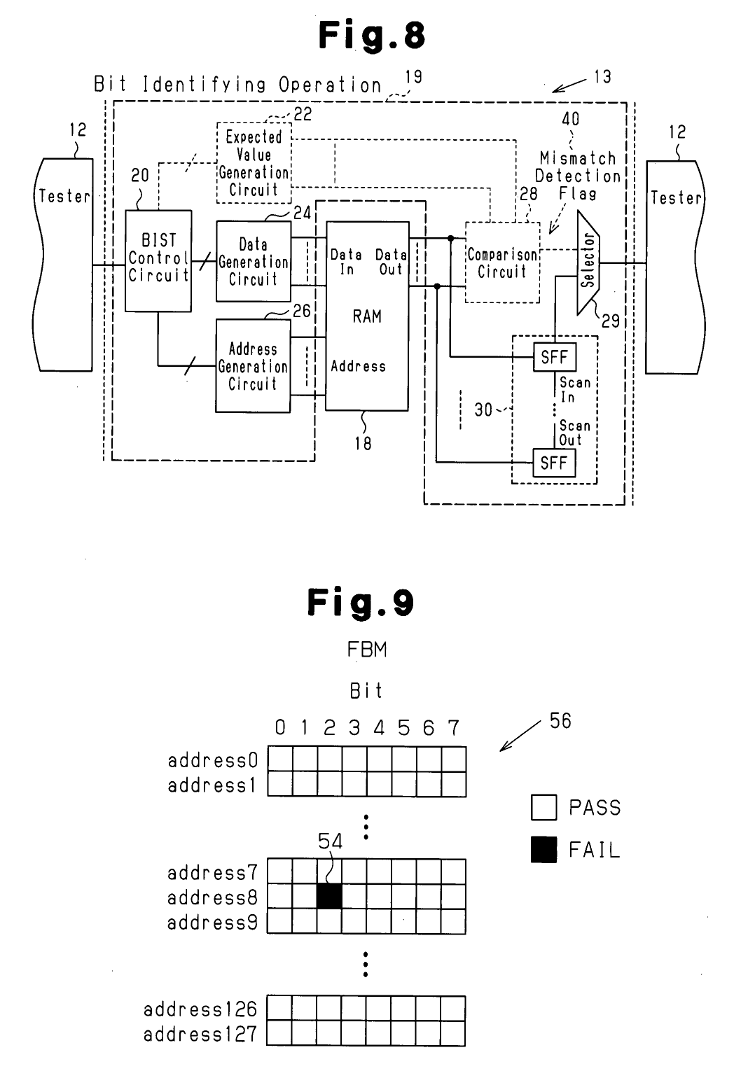

The BIST circuit 19 includes a BIST control circuit 20, an expected value generation circuit 22, a data generation circuit 24, an address generation circuit 26, a comparison circuit 28, a selector 29, and a read data register 30. The BIST circuit 19 functions in a shipment test mode and a bit identification mode. In the BIST circuit 19, the circuits that operated in the shipment test mode differs from the circuit that are operated in the bit identification mode. As shown in FIG. 4, in the shipment test mode, the read data register 30 is inactivated or suspended and does not operate. As shown in FIG. 8, in the bit identification mode, the expected value generation circuit 22 and the comparison circuit 28 are inactivated or suspended and do not operate.

The BIST control circuit 20 controls the operation of the RAM 18 by a command of n bits. The operation includes test algorithms of the RAM 18, which are “march” and “checker-board”, and the reading and writing of the RAM 18. Here, “march” refers to a pattern in which “0” is continuous or “1” is continuous, and “checker-board” refers to a pattern in which “0” and “1” are alternately repeated.

The expected value generation circuit 22 provides the comparison circuit 28 with an expected value of the data recorded in the memory cell selected by the address output from the address generation circuit 26. The data generation circuit 24 generates “march” data or “checker-board” data in accordance with a command from the BIST control circuit 20. The data from the data generation circuit 24 is output to the memory cell of the identified address in the RAM 18. The address generation circuit 26 generates an address sequence beginning from any start address and provides the address sequence to the RAM 18.

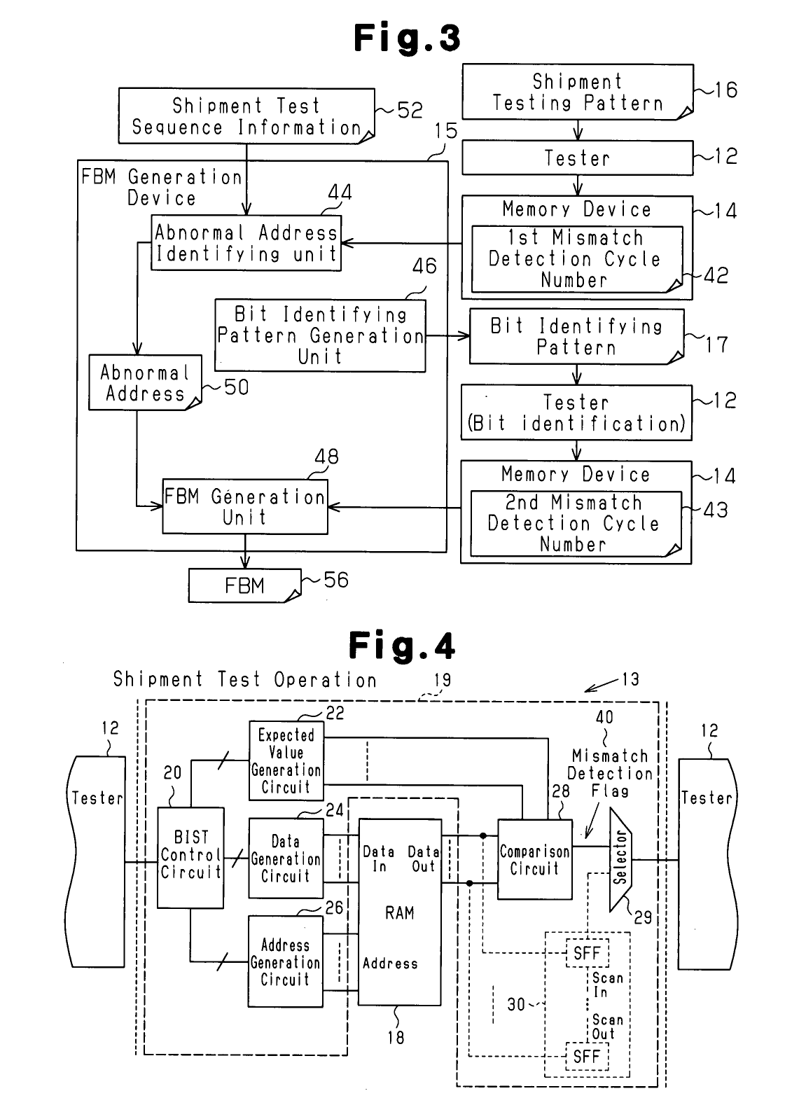

The comparison circuit 28 sets a mismatch detection flag (mismatch detection signal) 40 to “ON” when the data read from the RAM 18 and the expected value received from the expected value generation circuit 22 do not match. Further, the comparison circuit 28 provides the selector 29 with the cycle number of when the mismatch detection flag 40 is set to “ON” (referred to as first mismatch detection cycle number 42 (see FIG. 3)). The setting of the mismatch detection flag 40 to “ON” indicates that a failure was found in the shipment test. The cycle number (first mismatch detection cycle number 42) is provided from the selector 29 to the memory device 14 (FIG. 1) via the tester 12. The comparison circuit 28 includes registers having a sufficient number of bits to hold the read data of the RAM 18.

The read data register 30 includes a scan flip-flop (SFF) for the number of bits of the read data read from the RAM 18. This reduces the number of external pins necessary for retrieving read data. The selector 29 selects the output of the comparison circuit 28 (mismatch detection flag 40) or the output of the read data register 30. Then, the selector 29 provides the selected output to the tester 12 via the external pin of the semiconductor integrated circuit device 13.

As shown in FIG. 1, the memory device 14 stores data exchanged between the tester 12 and the FBM generation device 15. The memory device 14 is a typical magnetic disk device.

As shown in FIG. 3, the FBM generation device 15 includes an abnormal address identifying unit 44, a bit identifying pattern generation unit 46, and an FBM generation unit 48.

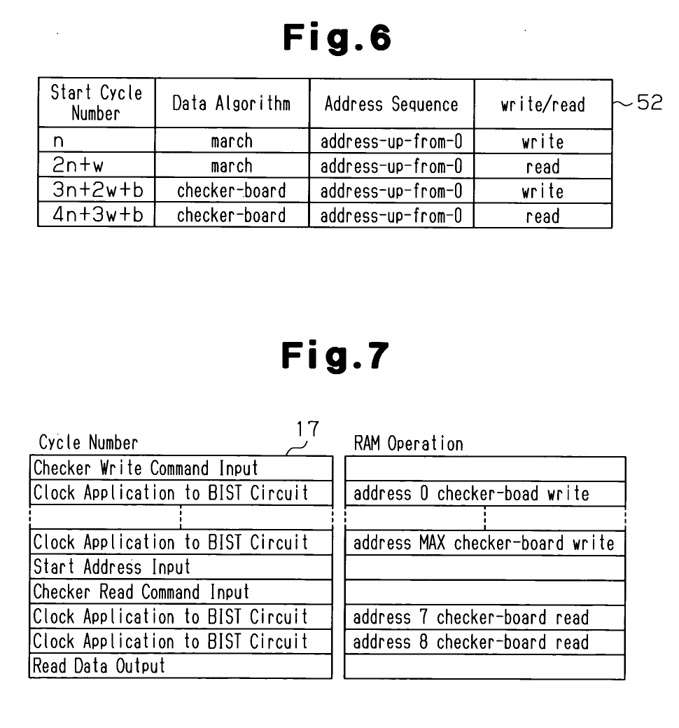

The abnormal address identifying unit 44 identifies an address at where there is a failure, that is, an abnormal address 50 from the addresses of the RAM 18. More specifically, the abnormal address identifying unit 44 identifies the address of the RAM 18 read and the test algorithm for reading the address when the mismatch detection flag 40 is set to “ON” from the first mismatch detection cycle number 42 and the shipment test sequence information 52. The shipment test sequence information 52 represents the operation sequence of the shipment test. The operation of the RAM 18 is described in the shipment test sequence information 52 in association with the cycle number. Thus, the operation the RAM 18 was carrying out at certain cycle number can be identified by referring to the shipment test sequence information 52. For instance, in the shipment test sequence information of FIG. 6, the data algorithm, the address sequence, and the distinction between write and read are specifically described for each start cycle number. The information may be generated at the same time as when generating the shipment testing pattern 16.

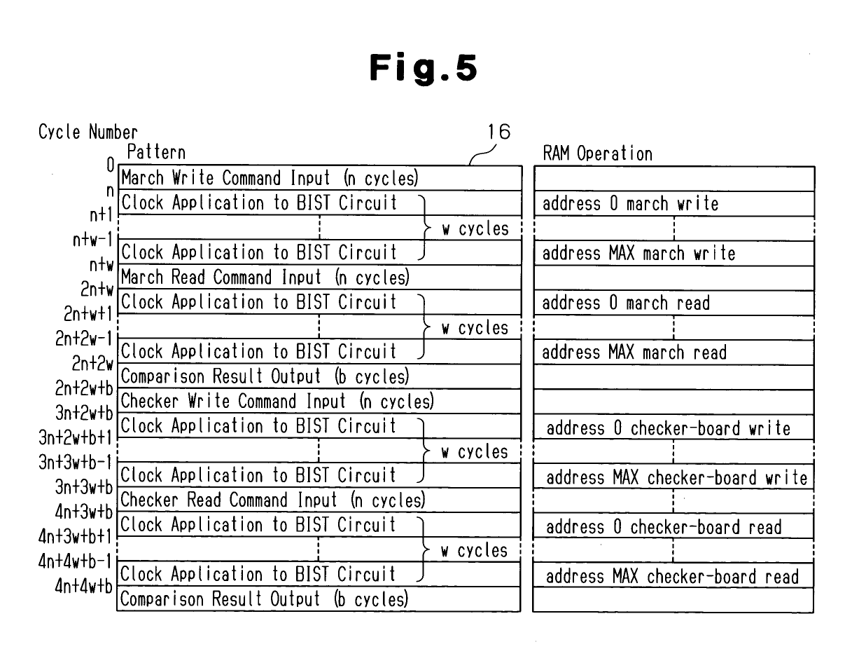

As shown in FIG. 3, the bit identifying pattern generation unit 46 generates the bit identifying pattern 17 to compensate for the information of bits that insufficient for generating the FBM 56. The bit identifying pattern 17 does not allow writing and reading to be performed at an address that determined to be normal in the shipment test. The bit identifying pattern 17 is a continuous pattern of only m+1 cycles from m patterns before the time at which the mismatch detection flag 40 is set to “ON” to the time at which the mismatch detection flag 40 is set to “ON”. Here, m is the number of cycles and is an integer greater than or equal to one. The bit identifying pattern 17 (see FIG. 7) is shorter than the shipment testing pattern 16 (see FIG. 5).

The FBM generation unit 48 identifies an abnormal bit 54 (see FIG. 9) from the second mismatch detection cycle number 43 (see FIG. 3) obtained by executing the bit identifying pattern 17 in the tester 12. More specifically, when the expected value contained in the bit identifying pattern 17 and the output of the RAM 18 during execution of the bit identifying pattern 17 do not match, the tester 12 outputs the cycle number at the time as the second mismatch detection cycle number 43. The second mismatch detection cycle number 43 is stored in the memory device 14. The cycle number at which the read data of the abnormal address 50 is output in the bit identifying pattern 17 is known since it is the pattern generated by the bit identifying pattern generation unit 46. Thus, the FBM generation unit 48 is capable of identifying the abnormal bit 54 from the second mismatch detection cycle number 43. The FBM generation unit 48 generates the FBM 56 from the previously identified abnormal address 50 and abnormal bit 54.

The operation of the failure diagnosis device 10 will now be described.

The shipment test performed by the failure diagnosis device 10 will now be discussed.

In the shipment test mode, the BIST circuit 19 is operated in accordance with the shipment testing pattern shown in FIG. 5. In other words, the shipment testing pattern 16 corresponds to the state of the BIST circuit 19 in the shipment test. In an n cycle of cycle numbers 0 to n, “march write command” is input to the BIST circuit 19. Here, n is an integer greater than or equal to one and represents the number of commands of the BIST control circuit 20. In a w cycle of cycle numbers n+1 to n+w−1, a clock signal is applied to the BIST circuit 19. This “march” writes the addresses 0 to MAX of the RAM 18 is written. Here, w is an integer greater than or equal to zero and represents the number of words of the RAM 18. In the n cycle of cycle numbers n+w to 2n+w, “march read command” is input to the BIST circuit 19. In the w cycle of cycle numbers 2n+w to 2n+2w−1, the clock signal is applied to the BIST circuit 19, and the addresses 0 to MAX of the RAM 18 are “march” read.

In a b cycle of cycle numbers 2n+2w to 2n+2w+b, the BIST circuit 19 outputs a comparison result. Here, b is an integer greater than or equal to zero and represents the number of bits of the RAM 18. In the n cycle of cycle numbers 2n+2w+b to 3n+2w+b, a “checker-board write command” is input to the BIST circuit 19. In the w cycle of cycle numbers 3n+2w+b+1 to 3n+3w+b−1, the clock signal is applied to the BIST circuit 19. This “checker-board” writes addresses 0 to MAX.

In the n cycle of cycle numbers 3n+3w+b to 4n+3w+b, a “checker-board read command” is input to the BIST circuit. In the w cycle of cycle number 4n+3w+b+1 to 4n+4w+b−1, the clock signal is applied to the BIST circuit 19, and addresses 0 to MAX are “checker-board” read. Finally, in the b cycle of cycle number 4n+4w+b, the comparison result is output from the BIST circuit 19.

If the output of the RAM 18 and the output of the expected value generation circuit 22 do not match, the comparison circuit 28 sets the mismatch detection flag 40 to “ON”. In this state, as shown in FIG. 4, the read data register 30 of the BIST circuit 19 is not selected, and the selector 29 provides the mismatch detection flag 40 to the tester 12. As shown in FIG. 3, the tester 12 then stores the cycle number executed when the mismatch detection flag 40 is set to “ON” in the memory device 14 as the first mismatch detection cycle number 42.

The operation of when the FBM generation device 15 identifies the abnormal address 50 will now be described.

The FBM generation device 15 identifies the test algorithm and the address of the RAM 18 that was being read when a mismatch occurred, that is, the operation of the RAM 18 when a mismatch occurred, from the first mismatch detection cycle number 42 and the shipment test sequence information 52. FIG. 6 shows the shipment test sequence information 52 for the shipment testing pattern 16 of FIG. 5. The row of start cycle number n describes “march” writing in an ascending order from address 0 in start cycle number n and the subsequent cycle numbers. The row of start cycle number 2n+w describes “march” reading in an ascending order from address 0 in start cycle number 2n+w and the subsequent cycle numbers. The row of start cycle number 3n+2w+b describes “checker-board” writing in an ascending order from address 0 in start cycle number 3n+2w+b and the subsequent cycle numbers. The row of start cycle number 4n+3w+b describes “checker-board” reading in an ascending order from address 0 in start cycle number 4n+3w+b and the subsequent cycle numbers.

For example, a state in which n=4, w=128, and b=8 are satisfied and the mismatch detection flag 40 is set to “ON” at the cycle number 416 in the shipment test will be discussed. The cycle number “416” is “read checker-board” after 4n+3w+b=4×4+3×128+8=408. Since cycle number “416” is the ninth one from “408”, it is apparent that the “checker-board pattern” of the ninth address 8 (see FIG. 9) is read. The abnormal address 50 of the FBM 56 is identified in this manner.

The generation of the bit identifying pattern 17 by the failure diagnosis device 10 will now be described.

In order to start the read operation from n patterns before the mismatch occurred, the address generation circuit 26 sets an arbitrary start address, and the bit identifying pattern 17 sets the address n patterns before the mismatch occurred as the start address signal. Furthermore, to prevent reading from being performed after occurrence of the mismatch, the bit identifying pattern generation unit 46 of the FBM generation device 15 generates the pattern only until the mismatch occurrence. As a result, the bit identifying pattern 17 becomes shorter than the shipment testing pattern 16.

The bit identifying pattern generation unit 46 generates the bit identifying pattern 17 shown in FIG. 7 and provides the bit identifying pattern 17 to the tester 12. As described above, the bit identifying pattern 17 is for when the mismatch detection flag 40 is set to “ON” when reading the “checker-board pattern” of the ninth address 8 in the shipment test sequence information 52 shown in FIG. 6. The number of cycle m is “1”.

The operation of the failure diagnosis device 10 using the bit identifying pattern 17 will now be described.

The expected value generation circuit 22 and the comparison circuit 28 of the BIST circuit 19 are non-selective in the bit identification mode, as shown in FIG. 8. The BIST circuit 19 receives from the tester 12 the bit identifying pattern 17 generated by the bit identifying pattern generation unit 46 of the FBM generation device 15. In the bit identification mode, the BIST circuit 19 operates in accordance with the bit identifying pattern 17. In other words, the bit identifying pattern 17 corresponds to the state of the BIST circuit 19 during bit identification.

In the preferred embodiment, the address generation circuit 26 continuously generates the read address from one pattern before the address when the mismatch detection flag 40 is set to “ON” to the address when the mismatch detection flag 40 is set to “ON” so that the RAM 18 continuously performs the reading operation.

During the continuous operation, the data (read data) read from the RAM 18 is retrieved into the read data register 30. When reading is continuously performed until the mismatch detection flag 40 is set to “ON”, the read data at the time the mismatch detection flag 40 is set to “ON” is ultimately held in the read data register 30. The BIST circuit 19 provides the read data held in the read data register 30 to the tester 12. The tester 12 compares the provided read data with the expected value of the read data. The tester 12 provides the second mismatch detection cycle number 43 to the memory device 14 if the provided read data does not match the expected value.

The generation of the FBM 56 by the failure diagnosis device 10 will now be described.

The FBM generation device 15 identifies the abnormal bit 54 (see FIG. 9) from the second mismatch detection cycle number 43 obtained through execution the bit identifying pattern 17 by the tester 12 and generates the FBM 56 from the abnormal bit 54 and the abnormal address 50.

For example, it is assumed here that the read data output starts from the cycle number 70 in the bit identifying pattern 17 of FIG. 7. If the second mismatch detection cycle number 43 obtained in the operation using the bit identifying pattern 17 is “72”, it can be recognized that the read data stored in the third SFF is a mismatch. The abnormal data can be identified from the connecting relationship of the third SFF and the data out pin of the RAM 18. If the third SFF and the data out pin of the second bit of the RAM 18 are connected, the abnormal bit 54 becomes the second bit.

The FBM generation device 15 generates the FBM 56 from the abnormal address 50 and the abnormal bit 54. In the preferred embodiment, for example, the abnormal address is 8 and the abnormal bit 54 is the second bit. Thus, the FBM 56 shown in FIG. 9 is obtained.

The preferred embodiment has the advantages described below.

(1) The FBM generation device 15 identifies the abnormal address 50 from the first mismatch detection cycle number 42 obtained in the shipment test and the shipment test sequence information 52 used in the shipment test. The FBM generation device 15 generates the bit identifying pattern 17 to compensate for the information of the read data that is insufficient for the generation of the FBM 56. The FBM generation device 15 identifies the abnormal bit 54 from the second mismatch detection cycle number 43 obtained through execution of the bit identifying pattern 17 by the tester 12 and generates the FBM 56 from the abnormal bit 54 and the abnormal address 50. As a result, the time required for generating the FBM 56 is reduced since reading and writing are not performed on the addresses determined as being normal in the shipment test.

(2) The test pattern for generating the FBM 56 becomes short since reading and writing of the RAM 18 are not performed on the addresses determined as being normal in the shipment test. Thus, the memory of the tester 12 does not become insufficient.

(3) The serial input/output of address and data of the RAM 18 are not performed by using the BIST circuit 19 when generating the FBM 56. Thus, the test pattern for generating the FBM 56 becomes short, and the time required for generating the FBM 56 is reduced.

(4) The serial input/output of address and data of the RAM 18 are not performed by using the BIST circuit 19 when generating the FBM 56. Thus, the test pattern for generating the FBM 56 becomes short, the memory of the tester 12 does not become insufficient.

(5) Continuous operation of m+1 cycles from the address of m cycles before the address when the mismatch detection flag 40 is set to “ON” and the test algorithm when the mismatch detection flag 40 is set to “ON” to the address when the mismatch detection flag 40 is set to “ON” are performed. Therefore, if m is greater than or equal to one, faults that recur only in a continuous operation are also detected.

In the preferred embodiment, the bit identifying pattern generation unit 46 performs the continuous operation for only two cycles from one pattern before when the mismatch detection flag 40 is set to “ON” to when the mismatch detection flag 40 is set to “ON”. That is, m=1 but may be m=0. In this case, the bit identifying pattern 17 for continuous operation is not generated. However, a minimum bit identifying pattern 17 is generated. Therefore, the time required for the generation of the FBM 56 is further reduced.

In the preferred embodiment, all addresses are subject to the write sequence at the head of the bit identifying pattern 17. Instead, only the addresses 7 to 8 may be subject to the writing. However, abnormalities may occur due to influence of surrounding cells. Thus, the abnormality discovery rate would be improved by performing writing on the memory cells of each address.

It should be apparent to those skilled in the art that the embodiment may be embodied in many other specific forms without departing from the spirit or scope of the invention. Therefore, the present examples and embodiments are to be considered as illustrative and not restrictive, and the embodiment is not to be limited to the details given herein, but may be modified within the scope and equivalence of the appended claims.

What is claimed is:

1. A fail bit map generation device generating a fail bit map for a semiconductor memory device embedded in a semiconductor integrated circuit device, the fail bit map generation device generating the fail bit map in cooperation with a tester testing the semiconductor integrated circuit device and a built-in self-test circuit, embedded in the semiconductor integrated circuit device, diagnosing the semiconductor memory device, wherein the built-in self-test circuit sets a mismatch detection flag to ON when an output of the semiconductor memory device and an expected value generated by the built-in self-test circuit are mismatched during a period in which the tester is conducting a shipment test on the semiconductor integrated circuit device, the fail bit map generation device comprising:
an abnormal address identifying unit identifying an abnormal address from a first mismatch detection cycle number when the mismatch detection flag is set to ON and shipment test sequence information, which is a sequence of the shipment test;
a bit identifying pattern generation unit generating a bit identifying pattern, the bit identifying pattern being a pattern of m+1 cycles in which reading is started from a state of the built-in self-test circuit corresponding to m cycles before when the mismatch detection flag is set to ON and operation of the built-in self-test circuit is ended when the mismatch detection flag is set to ON; and
a fail bit map generation unit identifying an abnormal bit from a second mismatch detection cycle number indicating that the output of the semiconductor memory device, which is obtained when the tester tests the semiconductor memory device with the bit identifying pattern, and an expected value in the bit identifying pattern do not match and generating the fail bit map from the identified abnormal bit and the abnormal address.

2. The fail bit map generation device according to claim 1, wherein m of the m+1 cycles of the bit identifying pattern is greater than or equal to one.

3. The fail bit map generation device according to claim 1, wherein m of the m+1 cycles of the bit identifying pattern is zero.

4. The fail bit map generation device according to claim 1, wherein:
the abnormal address identifying unit reads the first mismatch detection cycle number stored in a memory device; and
the fail bit map generation unit reads the second mismatch detection cycle number stored in the memory device.

5. A method for generating a fail bit map for a semiconductor memory device embedded in a semiconductor integrated circuit device, the method generating the fail bit map in cooperation with a tester testing the semiconductor integrated circuit device and a built-in self test circuit, embedded in the semiconductor integrated circuit device, diagnosing the semiconductor memory device, wherein the built-in self-test circuit sets a mismatch detection flag to ON when an output of the semiconductor memory device and an expected value generated by the built-in self-test circuit are mismatched during a period in which the tester is conducting a shipment test on the semiconductor integrated circuit device, the method comprising:
specifying an abnormal address from a first mismatch detection cycle number when the mismatch detection flag is set to ON and shipment test sequence information, which is a sequence of the shipment test;
generating a bit identifying pattern, the bit identifying pattern being a pattern of m+1 cycles in which reading is started from a state of the built-in self-test circuit corresponding to m cycles before when the mismatch detection flag is set to ON and operation of the built-in self-test circuit is ended when the mismatch detection flag is set to ON; and
specifying an abnormal bit from a second mismatch detection cycle number indicating that the output of the semiconductor memory device, which is obtained when the tester tests the semiconductor memory device with the bit identifying pattern, and an expected value in the bit identifying pattern do not match and generating the fail bit map from the identified abnormal bit and the abnormal address.

6. The method according to claim 5, wherein m of the m+1 cycles of the bit identifying pattern is greater than or equal to one.

7. The method according to claim 5, wherein m of the m+1 cycles of the bit identifying pattern is zero.
